(19) United States
(12) Patent Application Publication
(10) Pub. No.: US 2026/0279739 A1
(43) Pub. Date: Sep. 17, 2026

(54) SHADOW RING FOR SUBSTRATE BOND PROTECTION IN PLASMA ETCH CHAMBER

(71) Applicant: Applied Materials, Inc., Santa Clara, CA (US)

(72) Inventors: Prashant V. JAVALI, Bengaluru (IN); Chang-Lin HSIEH, San Jose, CA (US); Sergio Fukuda SHOJI, San Jose, CA (US); Balachandra Jatak NARAYAN, Bengaluru (IN); Yogananda Vishwanath SARODE, Bangalore (IN); Benjamin SCHWARZ, San Jose, CA (US)

(21) Appl. No.: 19/457,991

(22) Filed: Jan. 23, 2026

Related U.S. Application Data
(63) Continuation of application No. PCT/US2025/019451, filed on Mar. 11, 2025.

(51) Int. Cl. H01J 37/32

(52) U.S. Cl. CPC H01J 37/32642; H01J 37/32467; H01J 37/32715; H01J 2237/20235; H01J 2237/3341

(57) ABSTRACT

Embodiments of shadow rings for use in process chambers are provided herein. In some embodiments, a shadow ring for use in a process chamber includes: an annular body having an annular notch disposed along a lower surface of the annular body, wherein a sidewall of the annular notch extends downward and radially outward or downward and radially inward to the lower surface of the annular body, and wherein an upper surface of the annular body includes an angled portion that extends downward and radially inward; and a plurality of tabs extending outwardly from the annular body, wherein each of the plurality of tabs includes an alignment slot formed on a lower surface of each tab.

### CROSS-REFERENCE TO RELATED APPLICATIONS

This application is a continuation application of International Application No. PCT/US2025/019451, filed Mar. 11, 2025, and entitled “SHADOW RING FOR SUBSTRATE BOND PROTECTION IN PLASMA ETCH CHAMBER,” the contents of which are hereby incorporated by reference in their entirety.

### FIELD

Embodiments of the present disclosure generally relate to substrate processing equipment.

### BACKGROUND

In the semiconductor industry, substrates comprising wafers bonded to glass carriers are widely used in various processing steps, particularly in applications where temporary support is required for thin or fragile wafers. These bonded substrates are essential in advanced manufacturing processes, such as wafer thinning, device patterning, and back-end-of-line (BEOL) processing. Typically, a bonding adhesive is applied to secure the wafer to the glass carrier, providing stability and preventing wafer damage during these procedures.

However, plasma processing, commonly used in semiconductor fabrication to etch material from a substrate or to deposit material on the substrate can adversely affect the adhesive used in wafer-to-carrier bonding. When exposed to plasma, the adhesive at the wafer edge is often attacked, leading to degradation and the release of particles. These particles can then be redeposited on an upper surface of the wafer, reducing integrity and yield.

Accordingly, the inventors have provided herein embodiments of process kits that reduce or prevent adhesive degradation and particle contamination during plasma exposure.

### SUMMARY

Embodiments of shadow rings for use in process chambers are provided herein. In some embodiments, a shadow ring for use in a process chamber includes: an annular body having an annular notch disposed along a lower surface of the annular body, wherein a sidewall of the annular notch extends downward and radially outward or downward and radially inward to the lower surface of the annular body, and wherein an upper surface of the annular body includes an angled portion that extends downward and radially inward; and a plurality of tabs extending outwardly from the annular body, wherein each of the plurality of tabs includes an alignment slot formed on a lower surface of each tab.

In some embodiments, a process kit includes: a shadow ring having an annular body having an annular notch disposed along a lower surface of the annular body, and a plurality of tabs extending outwardly from the annular body, wherein each of the plurality of tabs includes an alignment slot formed on a lower surface of each tab; and a liner having a tubular body and a plurality of pins extending radially inward from the tubular body, wherein each alignment slot of the plurality of tabs is configured to engage with a pin of the plurality of pins.

In some embodiments, a process chamber includes a chamber body having an interior volume disposed therein, a liner disposed in the interior volume having a tubular body and a plurality of pins extending radially inward from the tubular body; a shadow ring disposed in the interior volume, the shadow ring having an annular body that includes an annular notch disposed along a lower surface of the annular body and a plurality of tabs extending outwardly from the annular body, wherein each of the plurality of tabs includes an alignment slot formed on a lower surface of each tab and configured to engage with a pin of the plurality of pins of the liner; and a substrate support having a substrate support surface disposed in the interior volume, wherein the substrate support is disposed below the shadow ring.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber in accordance with at least some embodiments of the present disclosure.

FIG. 2 depicts a schematic side view of a process chamber having a substrate support in a transfer position in accordance with at least some embodiments of the present disclosure.

FIG. 3 depicts a schematic side view of a process chamber having a substrate support in a process position in accordance with at least some embodiments of the present disclosure.

FIG. 4 depicts a bottom isometric view of a shadow ring in accordance with at least some embodiments of the present disclosure.

FIG. 5 depicts a cross-sectional side view of a portion of a process kit in accordance with at least some embodiments of the present disclosure.

FIG. 6 depicts a cross-sectional side view of a portion of a process kit in accordance with at least some embodiments of the present disclosure.

FIG. 7 depicts a top view of a shadow ring in accordance with at least some embodiments of the present disclosure.

FIG. 8 depicts a bottom view of a shadow ring in accordance with at least some embodiments of the present disclosure.

FIG. 9 depicts a side view of a shadow ring in accordance with at least some embodiments of the present disclosure.

FIG. 10 depicts a cross-sectional view of a shadow ring taken along lines 10-10 of FIG. 7 in accordance with at least some embodiments of the present disclosure.

FIG. 11 depicts a cross-sectional view of a shadow ring taken along lines 11-11 of FIG. 7 in accordance with at least some embodiments of the present disclosure.

FIG. 12 depicts a top view of a two-part shadow ring in accordance with at least some embodiments of the present disclosure.

FIG. 13 depicts an isometric bottom view of a two-part shadow ring in accordance with at least some embodiments of the present disclosure.

FIG. 14 depicts a cross-sectional side view of a portion of a two-part shadow ring disposed on a quartz ring in accordance with at least some embodiments of the present disclosure.

FIG. 15 depicts a cross-sectional side view taken along line 15-15 of the two-part shadow ring of FIG. 12 in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of shadow rings for use in a process chamber are provided herein. The shadow ring, when disposed in the process chamber over a substrate, overlaps with an outer portion of the substate to reduce or prevent plasma exposure to an adhesive that bonds a wafer to a carrier plate such as a glass carrier plate. The shadow ring may advantageously be disposed in an interior volume of the process chamber to protect the substrate from plasma exposure while also allowing for a sufficient flow path for process gases. The shadow ring rests above a substrate transfer opening on a liner disposed in the process chamber when the process chamber is in a transfer position. In a process position, the shadow ring rests on a substrate support and over an outer edge region of the substrate. The shadow ring may also advantageously prevent backside polymer formation on backsides of the substrate due to plasma overreach to such surfaces. Backside polymer formation may cause contamination in the process chamber and impact the performance of the substrate.

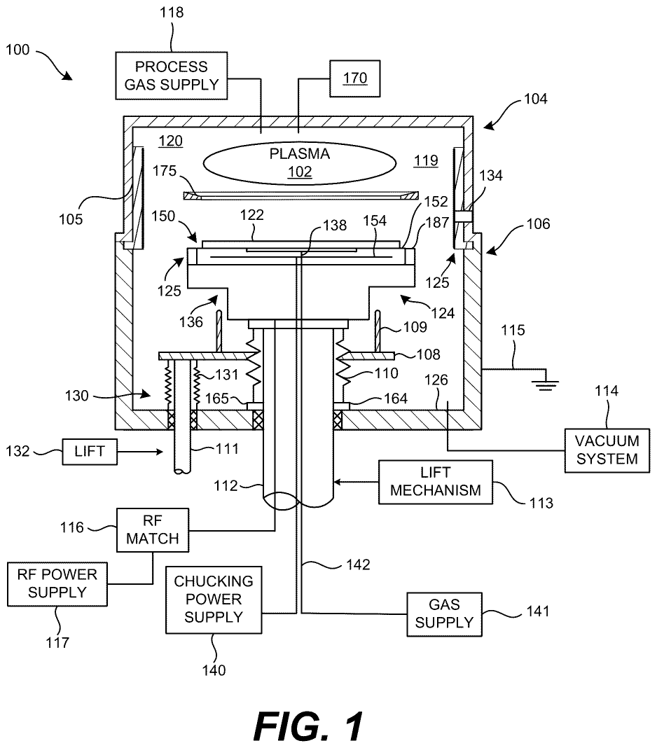

FIG. 1 depicts a schematic side view of a process chamber in accordance with at least some embodiments of the present disclosure. The process chamber, or chamber 100 (e.g., a plasma processing chamber), in some embodiments, may be an etch processing chamber. However, other types of processing chambers configured for different processes can also use or be modified for use with embodiments of the shadow rings described herein. The chamber 100 may be a vacuum chamber which is suitably adapted to maintain sub-atmospheric pressures within an interior volume 120 during substrate processing. The chamber 100 includes a chamber body 106 covered by a lid 104 which encloses a processing volume 119 located in the upper half of the interior volume 120. The chamber body 106 and lid 104 may be made of metal, such as aluminum. The chamber body 106 may be grounded via a coupling to ground 115.

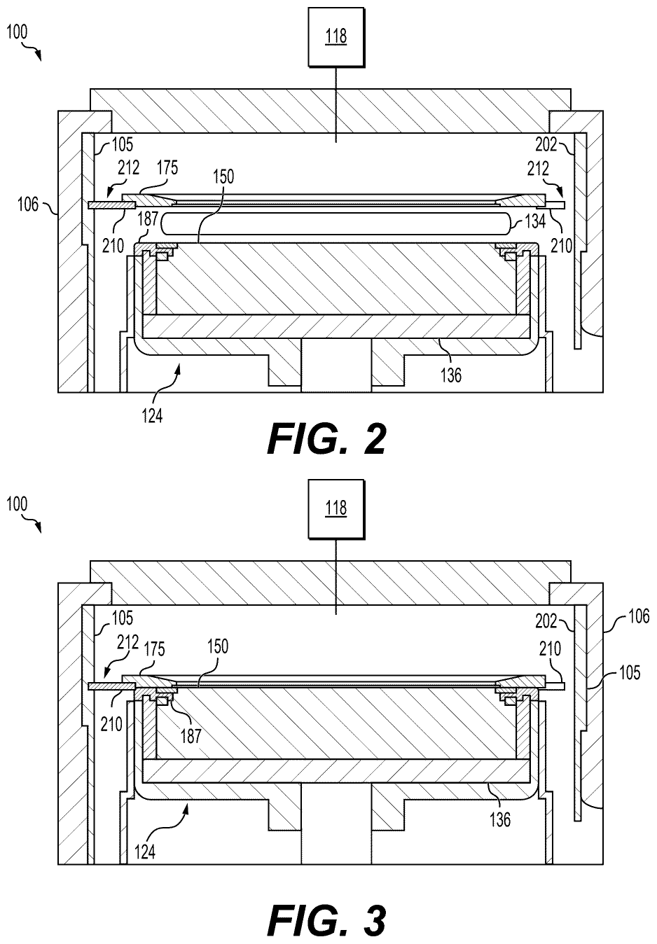

A substrate support 124 is disposed within the interior volume 120 to support and retain a substrate 122, such as a bonded semiconductor wafer. In some embodiments, the substrate 122 comprises a semiconductor wafer bonded to a carrier plate such as a glass carrier plate with a suitable glue or adhesive. The substrate support 124 may generally comprise an electrostatic chuck 150 (described in more detail below with respect to FIGS. 2-3) and a hollow support shaft 112 for supporting the electrostatic chuck 150. The electrostatic chuck 150 comprises a ceramic plate 152 having one or more electrodes 154 disposed therein and a cooling plate 136. The hollow support shaft 112 provides a conduit to provide, for example, backside gases, process gases, fluids, coolants, power, or the like, to the electrostatic chuck 150.

In some embodiments, the hollow support shaft 112 is coupled to a lift mechanism 113, such as an actuator or motor, which provides vertical movement of the substrate support 124 between an upper, processing position (as shown in FIG. 3) and a lower, transfer position (shown in FIG. 2). A bellows assembly 110 is disposed about the hollow support shaft 112 and is coupled between the electrostatic chuck 150 and a bottom surface 126 of chamber 100 to provide a flexible seal that allows vertical motion of the electrostatic chuck 150 while preventing loss of vacuum from within the chamber 100. The bellows assembly 110 also includes a lower bellows flange 164 in contact with an o-ring 165 or other suitable sealing element which contacts the bottom surface 126 to help prevent loss of chamber vacuum.

The chamber 100 includes a process kit 125 comprising one or more components configured to protect chamber components such as the chamber body 106 or substrate support 124 from unwanted deposition. For example, the process kit 125 may include a liner 105 disposed in the interior volume 120 to prevent unwanted reaction between the chamber body 106 and ionized process material. In some embodiments, the liner 105 is disposed in an upper portion of the interior volume 120 and adjacent the chamber body 106. The liner 105 may be made of aluminum or other suitable material. In some embodiments, the liner 105 was coated with yttrium oxide. The process kit 125 includes a shadow ring 175 disposed above the substrate 122 to protect an outer edge of the substrate 122. That is, the inner diameter of the shadow ring 175 is less than an outer diameter of the substrate 122 such that the shadow ring 175 advantageously blocks plasma bombardment of glue or adhesive exposed at an edge of the substrate 122.

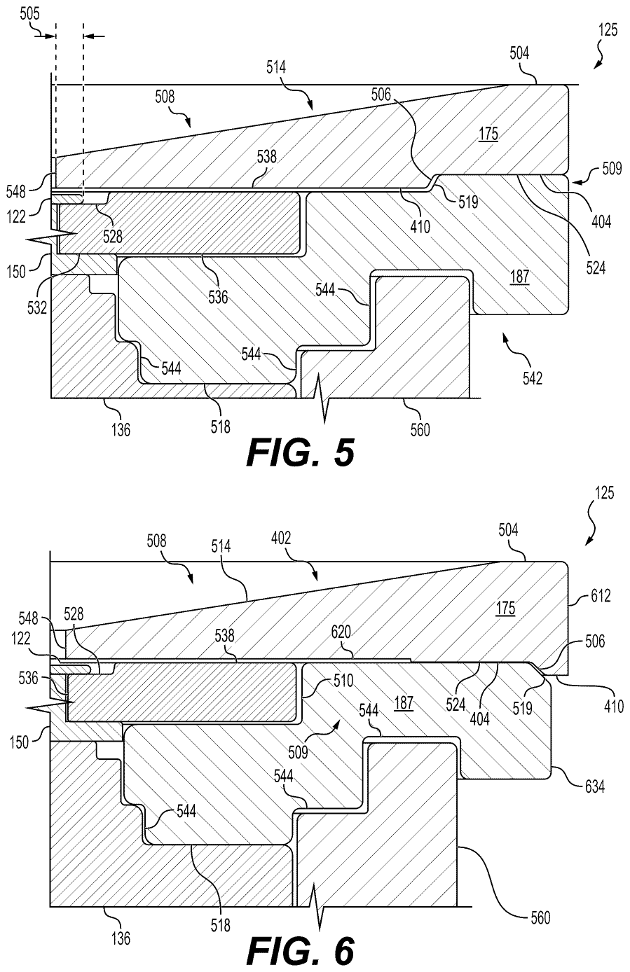

The process kit 125 may include a quartz ring 187 (described in more detail below with respect to FIGS. 5-6) disposed about the ceramic plate 152. The quartz ring 187 advantageously provides edge protection for the substrate 122 during processing as well as enhances thermal uniformity around edges of the substrate 122. The quartz ring 187 may also provide a resting surface for the shadow ring 175 when the substrate support 124 is in a processing position.

The hollow support shaft 112 provides a conduit for coupling a backside gas supply 141, a chucking power supply 140, and RF sources (e.g., RF plasma power supply 170 and a bias power supply 117) to the electrostatic chuck 150. In some embodiments, RF energy supplied by the RF plasma power supply 170 may have a frequency of about 40 MHz or greater. The backside gas supply 141 is disposed outside of the chamber body 106 and supplies heat transfer gas to the electrostatic chuck 150. In some embodiments, a RF plasma power supply 170 and a bias power supply 117 are coupled to the electrostatic chuck 150 via respective RF match networks (only RF match network 116 shown). In some embodiments, the substrate support 124 may alternatively include AC, DC, or RF bias power.

The chamber body 106 includes a transfer slot 134 for transferring the substrate 122 into and out of the interior volume 120. A substrate lift 130 can include lift pins 109 mounted on a platform 108 connected to a shaft 111 which is coupled to a second lift mechanism 132 for raising and lowering the substrate lift 130 so that the substrate 122 may be placed on or removed from the electrostatic chuck 150 once disposed in the interior volume 120. The electrostatic chuck 150 may include through holes to receive the lift pins 109. A bellows assembly 131 is coupled between the substrate lift 130 and bottom surface 126 to provide a flexible seal which maintains the chamber vacuum during vertical motion of the substrate lift 130.

In some embodiments, the electrostatic chuck 150 includes gas distribution channels 138 extending from a lower surface of the electrostatic chuck 150 (e.g., bottom surface of the cooling plate 136) to various openings in an upper surface of the electrostatic chuck 150 or lower surface of the quartz ring 187. The gas distribution channels 138 are configured to provide backside gas, such as nitrogen (N) or helium (He), to the top surface of the electrostatic chuck 150 or lower surface of the quartz ring 187 to act as a heat transfer medium. The gas distribution channels 138 are in fluid communication with the backside gas supply 141 via gas conduit 142 to control the temperature and/or temperature profile of the electrostatic chuck 150 during use.

The chamber 100 is coupled to and in fluid communication with a vacuum system 114 which includes a throttle valve (not shown) and vacuum pump (not shown) which are used to exhaust the chamber 100. The pressure inside the chamber 100 may be regulated by adjusting the throttle valve and/or vacuum pump. The chamber 100 is also coupled to and in fluid communication with a process gas supply 118 which may supply one or more process gases to the chamber 100 for processing a substrate disposed therein.

In operation, for example, a plasma 102 may be created in the interior volume 120 to perform one or more processes. The plasma 102 may be created by coupling power from a plasma power source (e.g., RF plasma power supply 170) to a process gas via one or more electrodes near or within the interior volume 120 to ignite the process gas and creating the plasma 102. A bias power may also be provided from a bias power supply (e.g., bias power supply 117) to the one or more electrodes 154 within the electrostatic chuck 150 to attract ions from the plasma towards the substrate 122.

FIG. 2 depicts a schematic side view of a process chamber, or chamber 100, having a substrate support 124 in a transfer position in accordance with at least some embodiments of the present disclosure. FIG. 3 depicts a schematic side view of the chamber 100 having a substrate support 124 in a process position in accordance with at least some embodiments of the present disclosure. In some embodiments, the liner 105 includes a tubular body 202 and plurality of pins 210 extending radially inward from the tubular body 202. In some embodiments, the transfer slot 134 may extend through the tubular body 202. The plurality of pins 210 may be disposed above the transfer slot 134. In some embodiments, a gap 212 is disposed between the tubular body 202 of the liner 105 and an outermost surface of the shadow ring 175.

The plurality of pins 210 may be configured to support the shadow ring 175 when in the transfer position, or lower position. In the process position, or upper position, the substrate support 124 may be raised so that shadow ring 175 may rest on the substrate support 124, for example, via the quartz ring 187 disposed thereon. In some embodiments, in the process position, the substrate support 124 is raised such that the shadow ring 175 is elevated off of the plurality of pins 210. The substrate support 124 is selectively movable between the lower position and the upper position. In some embodiments, the plurality of pins 210 comprises three pins. In some embodiments, the three pins are arranged asymmetrically.

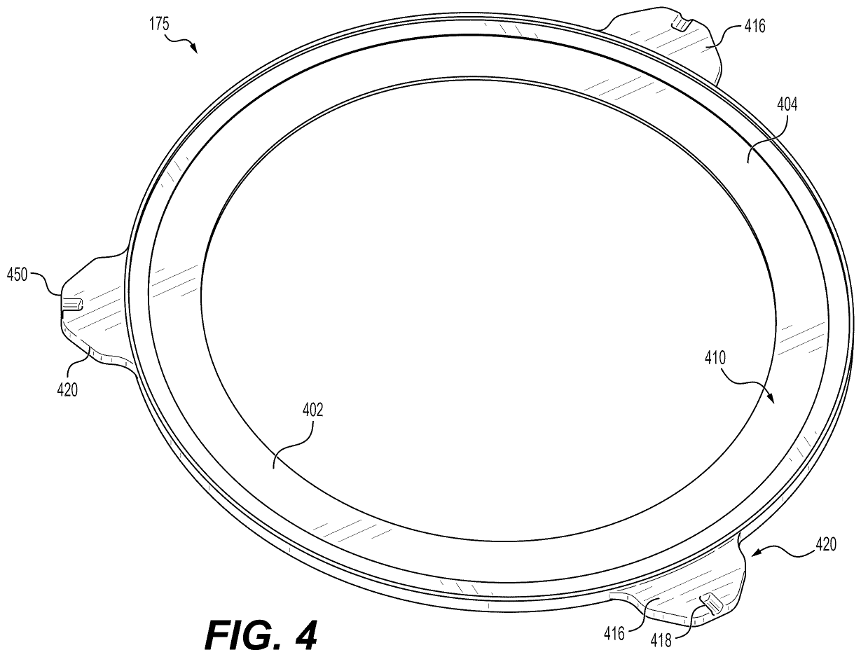

FIG. 4 depicts a bottom isometric view of a shadow ring 175 in accordance with at least some embodiments of the present disclosure. In some embodiments, the shadow ring 175 includes an annular body 402 having an annular notch 404 disposed along a lower surface 410 of the annular body 402. In some embodiments, the annular body 402 is made of silicon such as single crystal silicon, quartz, anodized aluminum, or a ceramic material. In some embodiments, a plurality of tabs 420 extend outwardly from the annular body 402. In some embodiments, the plurality of tabs 420 are uniformly spaced along the annular body 402.

In some embodiments, each of the plurality of tabs 420 includes an alignment slot 418 formed on a lower surface 416 of each tab. Each alignment slot of the plurality of tabs 420 is configured to engage with a pin of the plurality of pins 210. In some embodiments, the alignment slot 418 extends radially inward from an outermost surface 450 of each tab. The plurality of pins 210 may include any suitable cross-sectional shape, for example, a circular shape, an oval shape, a rectangular shape, or the like. The plurality of tabs 420 advantageously allow for the shadow ring 175 to rest on the plurality of pins 210 while allowing for an outer diameter of the annular body 402 to be smaller to provide more flow conductance between the liner 105 and the shadow ring 175. In some embodiments, a radially inner sidewall of the alignment slot 418 extends downward and radially inward so that the shadow ring 175 can self-center on the plurality of pins 210. In some embodiments, the gap 212 between an outer sidewall of the plurality of tabs 420 and the tubular body 202 is about 0.05 inches to about 0.2 inches.

FIG. 5 depicts a cross-sectional side view of a portion of a process kit 125 in accordance with at least some embodiments of the present disclosure. The innermost diameter of the shadow ring 175 is less than an outer diameter of the substrate 122 to cover an edge of the substrate 122, to advantageously protect adhesive from the edge region of the substrate 122 from plasma exposure, reducing degradation of the adhesive, release of particles, and decoupling of a wafer from a carrier plate due to degradation of the adhesive. In some embodiments, the shadow ring 175 provides an overlap 505 of about 1 mm to about 3 mm with the edge region of the substrate 122. If the overlap 505 is greater than about 3 mm, the yield, or usable area, of the substrate 122 may be affected.

In some embodiments, as depicted in FIG. 5, a sidewall 506 of the annular notch 404 of the shadow ring 175 extends downward and radially inward to the lower surface 410 of the annular body 402. The sidewall 506 is advantageously angled at a non-orthogonal angle to self-center the shadow ring 175 when disposed on the quartz ring 187. Alignment of the shadow ring 175 with respect to the substrate 122 is important to ensure more uniform overlap between the shadow ring 175 and the edge region of the substrate 122. In some embodiments, an upper surface 508 of the annular body 402 includes an angled portion 514 that extends downward and radially inward. In some embodiments, the upper surface 508 of the annular body 402 includes a horizontal portion 504 disposed radially outward of the angled portion 514.

In some embodiments, the quartz ring 187 rests on the substrate support 124, for example, an outer ledge 518 of the substrate support 124. In some embodiments, the quartz ring 187 has an inner diameter greater than a diameter of an inner wall 548 of the shadow ring 175. In some embodiments, an upper surface 524 of the quartz ring 187 includes a raised portion 509 configured to extend into the annular notch 404 and support the shadow ring 175 when disposed thereon. In some embodiments, the raised portion 509 includes a sidewall 519 disposed opposite and substantially parallel to the sidewall 506 of the shadow ring 175. In some embodiments, there is a gap between the sidewall 519 and the sidewall 506 to allow for thermal expansion.

In some embodiments, a lower surface 542 of the quartz ring 187 includes a plurality of steps 544. In some embodiments, the process kit 125 further includes a lower quartz ring 560 disposed about the cooling plate 136 to protect the cooling plate 136 from plasma bombardment. In some embodiments, an upper surface of the lower quartz ring 560 may extend into one or more openings formed by the plurality of steps 544 of the quartz ring 187 to form a tortuous path therebetween.

In some embodiments, the process kit 125 further comprises a collar ring 536 configured to be disposed in a second notch 510 of the quartz ring 187 and between the shadow ring 175 and the quartz ring 187. The collar ring 536 generally is designed to resist wear from ion bombardment and aids in more uniform plasma distribution across the substrate 122. For example, the collar ring 536 may be made of a same or similar material to an upper surface of the substrate 122 (e.g., silicon, quartz, anodized aluminum, or a ceramic material), to provide more uniform plasma at the edge region of the substrate 122. The collar ring 536 may rest on an outer ledge 532 of the electrostatic chuck 150. In some embodiments, the collar ring 536 includes a third notch 528 at an upper inner edge thereof to accommodate the substrate 122 therein.

In some embodiments, a gap 538 is disposed between the shadow ring 175 and the collar ring 536 when the shadow ring 175 is disposed on the quartz ring 187. In some embodiments, the gap 538 advantageously prevents particle formation from potential rubbing between the shadow ring 175 and the collar ring 536. In some embodiments, there is a gap disposed between the collar ring 536 and the quartz ring 187 to reduce or prevent particle formation from rubbing therebetween.

FIG. 6 depicts a cross-sectional side view of a portion of a process kit 125 in accordance with at least some embodiments of the present disclosure. In some embodiments, as depicted in FIG. 6, the sidewall 506 of the annular notch 404 of the shadow ring 175 extends downward and radially outward to the lower surface 410 of the annular body 402. In some embodiments, the lower surface 410 of the annular body 402 includes a second annular notch 620 disposed along an inner edge 618 of the annular body 402. The second annular notch 620 may create the gap 538 disposed between the shadow ring 175 and the collar ring 536 to reduce or prevent particle formation therebetween.

In some embodiments, a height of the annular body 402 only increases from an inner wall (e.g., the inner wall 548) of the annular body 402 to the horizontal portion 504 of the annular body. In some embodiments, the height of the annular body 402 does not decrease from the inner wall 548 to an outer wall 612 of the annular body 402, or in other words, only increases or stays the same from the inner wall 548 to the outer wall 612. In some embodiments, the inner wall 548 forms a substantially sharp edge with the lower surface 410 of the annular body 402. In some embodiments, the outer wall 612 of the annular body 402 has a plain surface and a substantially uniform surface finish. In some embodiments, the inner wall 548 has a plain surface and a substantially uniform surface finish. In some embodiments, the sidewall 506 of the annular notch 404 is disposed radially outward of the angled portion 514. In some embodiments, the sidewall 519 of the quartz ring 187 extends directly to an outermost surface 634 of the quartz ring 187.

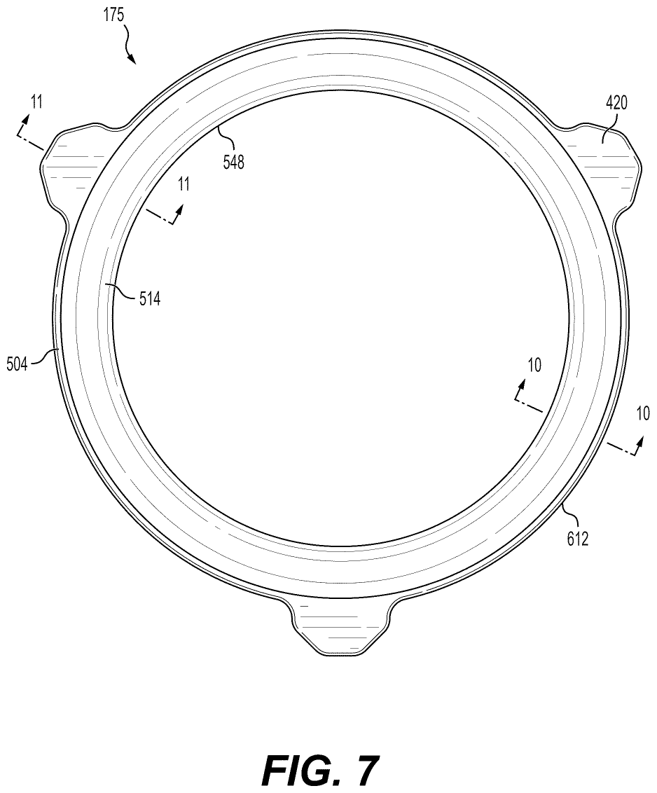

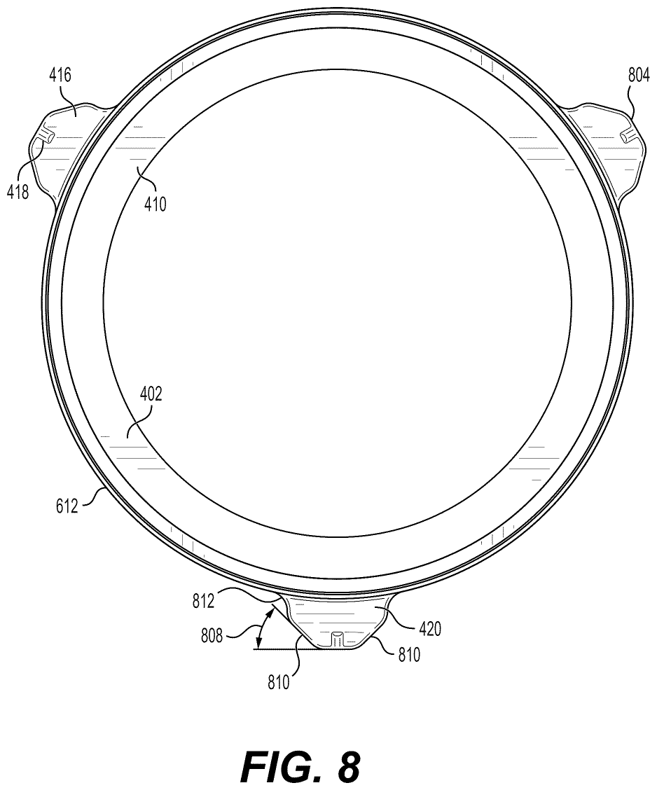

FIG. 7 depicts a top view of a shadow ring 175 in accordance with at least some embodiments of the present disclosure. FIG. 8 depicts a bottom view of the shadow ring 175 in accordance with at least some embodiments of the present disclosure. In some embodiments, an outermost sidewall 804 of the plurality of tabs 420 extends linearly or substantially linearly. In some embodiments, the plurality of tabs 420 include sidewalls 810 extending at an angle 808 from ends of the outermost sidewall 804. In some embodiments, the angle 808 is about 30 to about 60 degrees. In some embodiments, the plurality of tabs 420 include second sidewalls 812 extending from the sidewalls 810 to the outer wall 612 of the annular body 402. In some embodiments, the upper surface 508 of the annular body has a plain surface and a substantially uniform surface finish. In some embodiments, the lower surface 410 of the annular body has a plain surface and a substantially uniform surface finish. In some embodiments, a transition from the upper surface 508 of the annular body 402 to the outer wall 612 of the annular body 402 is rounded. In some embodiments, a transition from the upper surface 508 of the annular body 402 to the outer wall 612 of the annular body 402 is rounded. In some embodiments, all outward facing surfaces of the shadow ring 175 have a plain surface and a substantially uniform surface finish.

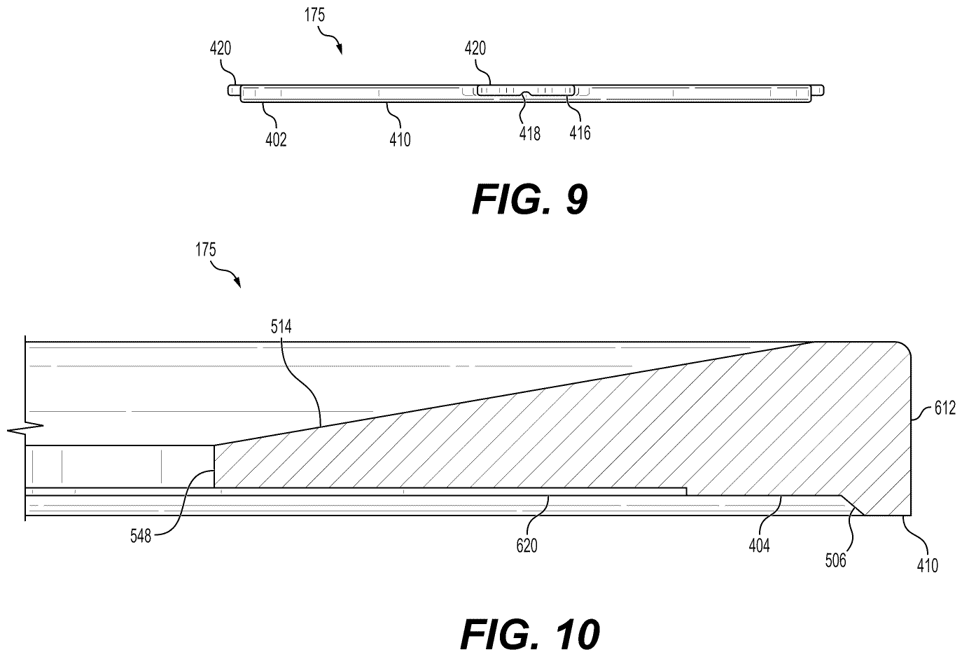

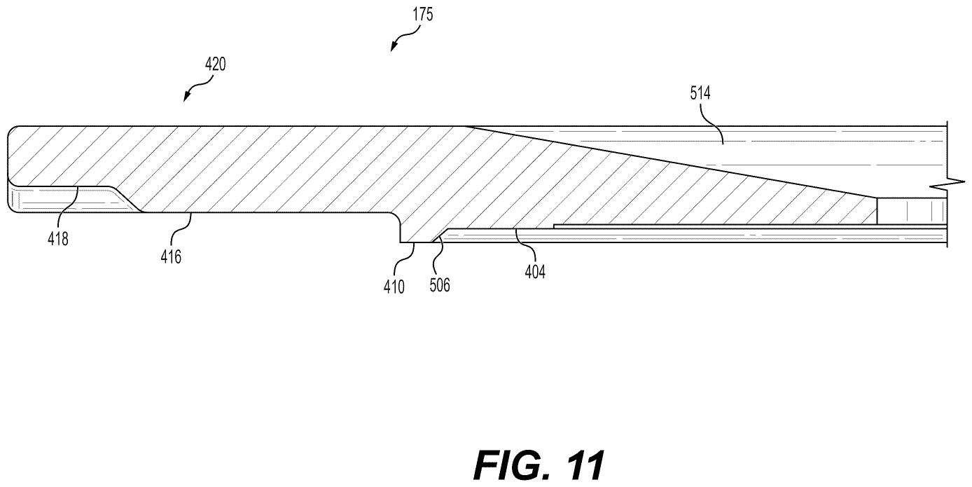

FIG. 9 depicts a side view of a shadow ring 175 in accordance with at least some embodiments of the present disclosure. FIG. 10 depicts a cross-sectional view of a shadow ring 175 taken along lines 10-10 of FIG. 7 in accordance with at least some embodiments of the present disclosure. FIG. 11 depicts a cross-sectional view of a shadow ring 175 taken along lines 11-11 of FIG. 7 in accordance with at least some embodiments of the present disclosure. In some embodiments, the lower surface 410 of the annular body 402 is offset from the lower surface 416 of the plurality of tabs 420.

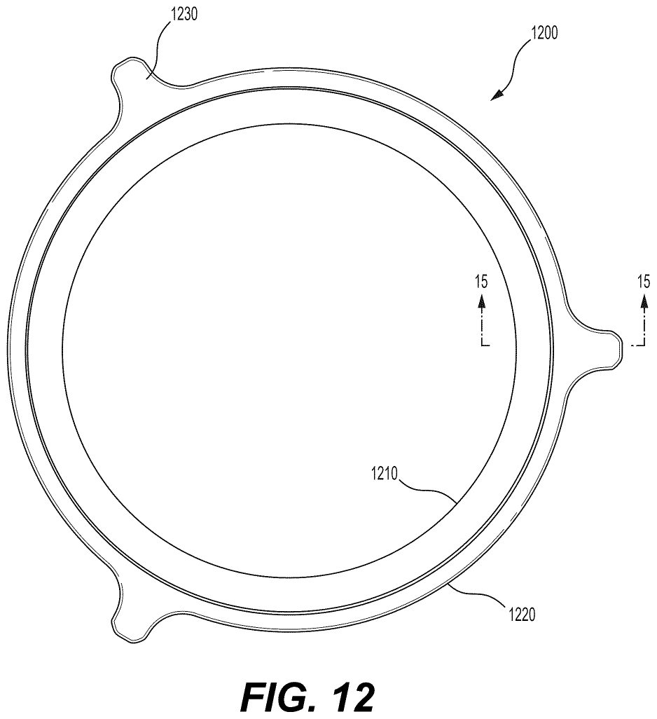

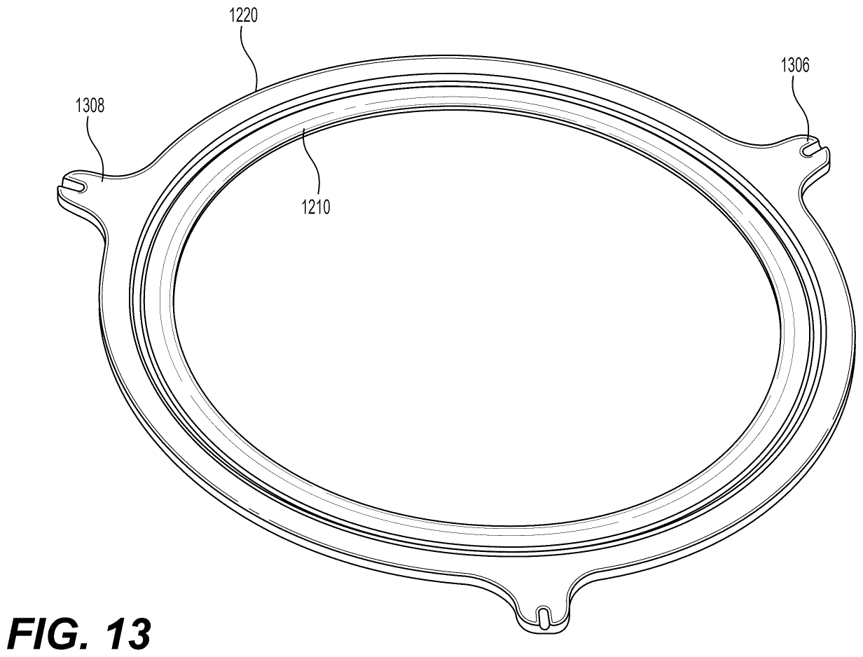

FIG. 12 depicts a top view of a two-part shadow ring in accordance with at least some embodiments of the present disclosure. FIG. 13 depicts an isometric bottom view of a two-part shadow ring in accordance with at least some embodiments of the present disclosure. The two-part shadow ring 1200 may be the shadow ring 175 discussed herein split into two separate components. For example, the two-part shadow ring 1200 may include an inner ring 1210 and an outer ring 1220. In some embodiments, the inner ring 1210 and the outer ring 1220 are made of different materials. For example, the inner ring 1210 may be made of silicon. In some embodiments, the outer ring 1220 is made of quartz. In some embodiments, the outer ring 1220 includes a plurality of tabs 1230 configured to engage with a pin of the plurality of pins 210.

The plurality of tabs 1230 may be similar to the plurality of tabs 420 discussed above. In some embodiments, each of the plurality of tabs 1230 includes an alignment slot 1306 formed on a lower surface 1308 of each tab. In some embodiments, each alignment slot 1306 of the plurality of tabs 1230 is configured to engage with a pin of the plurality of pins 210 to advantageously self-center the two-part shadow ring 1200 on the plurality of pins 210.

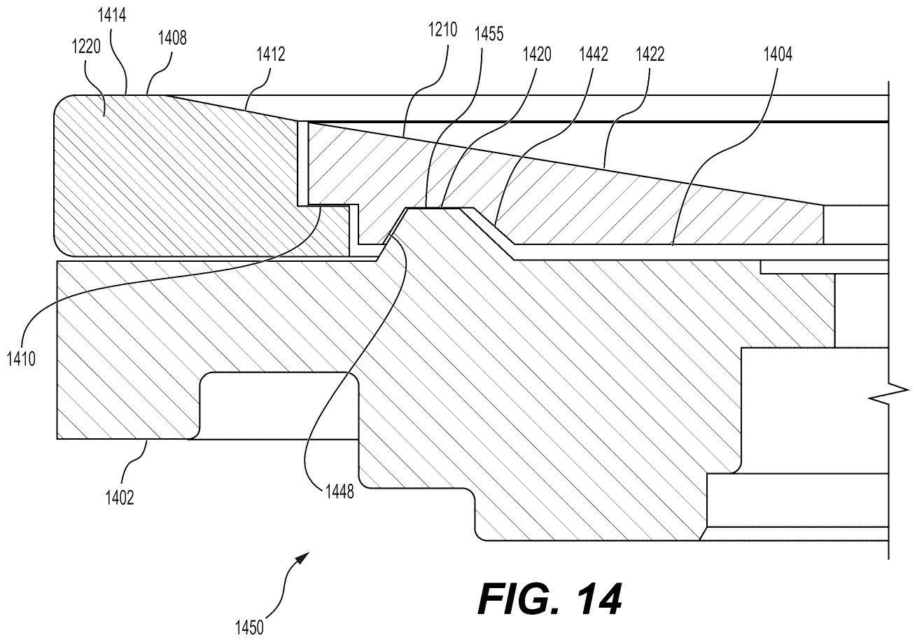

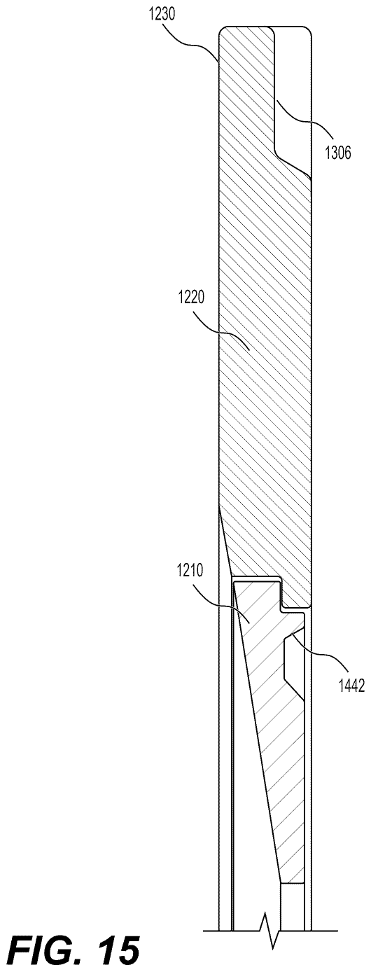

FIG. 14 depicts a cross-sectional side view of a portion of a two-part shadow ring 1200 disposed on a quartz ring 1402 in accordance with at least some embodiments of the present disclosure. FIG. 15 depicts a cross-sectional side view taken along line 15-15 of the two-part shadow ring of FIG. 12 in accordance with at least some embodiments of the present disclosure. The outer ring 1220 of the two-part shadow ring 1200 may include an inner ledge 1410. The inner ring 1210 may rest on the outer ring 1220 such that when the outer ring 1220 is raised, the inner ring 1210 is raised via the inner ledge 1410. In some embodiments, the inner ring 1210 only interacts, or touches, the outer ring 1220 along the inner ledge 1410. In some embodiments, an upper surface 1408 of the outer ring 1220 includes an inclined portion 1412. In some embodiments, the upper surface 1408 includes a substantially horizontal portion 1414 disposed radially outward of the inclined portion 1412. In some embodiments, a lower surface of the quartz ring 1402 includes a plurality of steps 1450. For example, the plurality of steps 1450 includes three or more steps.

In some embodiments, an upper surface 1422 of the inner ring 1210 is inclined. In some embodiments, the upper surface 1422 is inclined at an angle similar to the inclined portion 1412. The inner ring 1210 includes an annular notch 1420 disposed along a lower surface 1404 of the inner ring 1210. In some embodiments, an inner sidewall 1442 of the annular notch 1420 extends downward and radially inward to the lower surface 1404. In some embodiments, an outer sidewall 1448 of the annular notch 1420 extends downward and radially outward to the lower surface 1404. The annular notch 1420 is configured to accommodate a raised portion 1455 of the quartz ring 1402. For example, when in the processing position, the quartz ring 1402 is configured to raise the inner ring 1210 via the annular notch 1420. The outer sidewall 1448 and the inner sidewall 1442 being angled upward and radially inward or upward and radially outward advantageously self-centers the inner ring 1210 with respect to the quartz ring 1402 and thus also with respect to the substrate 122 when disposed on the substrate support 124.

While the foregoing is directed to embodiments of the present disclosure, other and further embodiments of the disclosure may be devised without departing from the basic scope thereof.

1. A shadow ring for use in a process chamber, comprising:
an annular body having an annular notch disposed along a lower surface of the annular body, wherein a sidewall of the annular notch extends downward and radially outward or downward and radially inward to the lower surface of the annular body, and wherein an upper surface of the annular body includes an angled portion that extends downward and radially inward; and
a plurality of tabs extending outwardly from the annular body, wherein each of the plurality of tabs includes an alignment slot formed on a lower surface of each tab.

2. The shadow ring of claim 1, wherein the lower surface of the annular body includes a second annular notch disposed along an inner edge of the annular body.

3. The shadow ring of claim 2, wherein the upper surface of the annular body includes a horizontal portion disposed radially outward of the angled portion.

4. The shadow ring of claim 1, wherein the annular body comprises an inner ring and an outer ring separate from the inner ring.

5. The shadow ring of claim 1, wherein the annular body is made of silicon, quartz, anodized aluminum, or a ceramic material.

6. The shadow ring of claim 1, wherein a height of the annular body only increases from an innermost diameter of the annular body to an outermost diameter of the annular body.

7. The shadow ring of claim 1, wherein the alignment slot extends radially inward from an outermost surface of each tab.

8. A process kit, comprising:
a shadow ring having an annular body having an annular notch disposed along a lower surface of the annular body, and a plurality of tabs extending outwardly from the annular body, wherein each of the plurality of tabs includes an alignment slot formed on a lower surface of each tab; and
a liner having a tubular body and a plurality of pins extending radially inward from the tubular body, wherein each alignment slot of the plurality of tabs is configured to engage with a pin of the plurality of pins.

9. The process kit of claim 8, further comprising a quartz ring having an inner diameter greater than an inner diameter of the shadow ring, and wherein an upper surface of the quartz ring includes a raised portion configured to extend into the annular notch and support the shadow ring when disposed thereon.

10. The process kit of claim 9, wherein the quartz ring includes a second notch at an upper inner edge thereof.

11. The process kit of claim 9, further comprising a collar ring configured to be disposed in a second notch of the quartz ring and between the shadow ring and the quartz ring.

12. The process kit of claim 11, wherein the collar ring includes a third notch at an upper inner edge thereof to accommodate a substrate therein.

13. The process kit of claim 11, wherein a gap is disposed between the shadow ring and the collar ring when the shadow ring is disposed on the quartz ring.

14. The process kit of claim 9, wherein a lower surface of the quartz ring includes a plurality of steps.

15. The process kit of claim 8, wherein a sidewall of the annular notch of the shadow ring extends downward and radially outward or downward and radially inward to the lower surface of the annular body.

16. A process chamber, comprising:
a chamber body having an interior volume disposed therein,
a liner disposed in the interior volume having a tubular body and a plurality of pins extending radially inward from the tubular body;
a shadow ring disposed in the interior volume, the shadow ring having an annular body that includes an annular notch disposed along a lower surface of the annular body and a plurality of tabs extending outwardly from the annular body, wherein each of the plurality of tabs includes an alignment slot formed on a lower surface of each tab and configured to engage with a pin of the plurality of pins of the liner; and
a substrate support having a substrate support surface disposed in the interior volume, wherein the substrate support is disposed below the shadow ring.

17. The process chamber of claim 16, further comprising:
a quartz ring having an inner diameter greater than an inner diameter of the shadow ring disposed on the substrate support, and wherein an upper surface of the quartz ring includes a raised portion configured to extend into the annular notch and support the shadow ring when disposed thereon.

18. The process chamber of claim 16, wherein the substrate support is selectively movable between a lower position, where the shadow ring rests on the plurality of pins of the liner and an upper position, where the shadow ring rests on the substrate support and is elevated off of the plurality of pins.

19. The process chamber of claim 16, wherein the liner includes a transfer slot, and the plurality of pins are disposed above the transfer slot.

20. The process chamber of claim 16, wherein a gap is disposed between the tubular body of the liner and an outermost surface of the shadow ring.
